(19) United States
(12) Patent Application Publication
(10) Pub. No.: US 2017/0200786 A1
(43) Pub. Date: Jul. 13, 2017

(54) FABRICATION OF TRANSISTOR-BASED SEMICONDUCTOR DEVICE USING CLOSED-LOOP FINS

(71) Applicant: GLOBALFOUNDRIES Inc., Grand Cayman (KY)

(72) Inventors: Hui ZANG, Guilderland, NY (US); Min-hwa CHI, San Jose, CA (US)

(73) Assignee: GLOBALFOUNDRIES Inc., Grand Cayman (KY)

(21) Appl. No.: 14/993,543

(22) Filed: Jan. 12, 2016

(51) Int. Cl. H01L 29/06; H01L 27/11; H01L 21/308; H01L 27/12; H01L 21/84; H01L 21/3065

(52) U.S. Cl. CPC H01L 29/0692; H01L 21/845; H01L 21/3065; H01L 21/308; H01L 27/1211; H01L 27/1104; H01L 27/1116

(57) ABSTRACT

Shaped mandrels are used to form closed-loop spacer(s) around the shaped mandrels, after which the shaped mandrels are removed, leaving a closed-loop fin. A transistor includes U-shaped portion(s) of a closed-loop fin, and a gate across channel region(s) of the U-shaped portion(s) of a closed-loop fin. A semiconductor structure includes portion(s) of closed-loop fin(s), and transistors formed from the portion(s) of closed-loop fin(s).

### BACKGROUND OF THE INVENTION

Technical Field

The present invention generally relates to fabrication of transistor-based semiconductor devices. More particularly, the present invention relates to fabrication of transistor-based semiconductor devices using closed-loop fins.

Background Information

In conventional FinFET fabrication, long, tall and skinny fins are used. However, such a structure may be unstable and include unwanted defects.

Thus, a need continues to exist for ways to improve stability and defects in fins.

### SUMMARY OF THE INVENTION

The shortcomings of the prior art are overcome and additional advantages are provided through the provision, in one aspect, of a method of forming a two-dimensional fin. The method includes forming one or more rectangular mandrels, forming one or more closed-loop spacers around the one or more rectangular mandrels, and removing the one or more rectangular mandrels, leaving the one or more closed-loop spacers.

In accordance with another aspect, a transistor is provided. The transistor includes at least one U-shaped portion of a closed-loop fin, and a gate across at least one channel region of the at least one U-shaped portion of a closed-loop fin.

In accordance with yet another aspect, a semiconductor structure is provided. The semiconductor structure includes at least one portion of one or more closed-loop fins, and a plurality of transistors formed from the at least one portion of one or more closed-loop fins.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a top-down view of one example of a starting semiconductor structure, the structure including a base (for example, a substrate with hard mask thereover and a mandrel material on top) with a rectangular mandrel thereover, in accordance with one or more aspects of the present invention.

FIG. 2 depicts one example of the structure of FIG. 1 after forming a spacer around the mandrel, in accordance with one or more aspects of the present invention.

FIG. 3 depicts one example of the structure of FIG. 2 after removing the mandrel (e.g., plasma etching selective to spacer), leaving a closed-loop spacer, in accordance with one or more aspects of the present invention.

FIG. 4 depicts one example of the structure of FIG. 3 after optionally forming inner and outer spacers (e.g., nitride) around the spacer by using the spacer as a mandrel. The removal of the mandrel may be performed, for example, using plasma etching with selectivity to the inner and outer spacer material, in accordance with one or more aspects of the present invention.

FIG. 5 depicts one example of the structure of FIG. 4 after removing the original closed-loop spacer using a selective etch, in accordance with one or more aspects of the present invention.

FIG. 6 depicts a three-dimensional view of one example of a starting semiconductor structure for fabrication of the mandrel in FIG. 1, the structure including a semiconductor substrate, a hard mask layer over the substrate and a layer of mandrel (e.g., silanol (Si—O—H), patterned in the Y direction, in accordance with one or more aspects of the present invention.

FIG. 7 depicts one example of the structure of FIG. 6 after formation of a blanket organic dielectric layer (ODL), followed by planarization (e.g., chemical-mechanical polishing process), in accordance with one or more aspects of the present invention.

FIG. 8 depicts one example of the structure of FIG. 7 after formation and patterning of a lithographic blocking layer in the X direction, in accordance with one or more aspects of the present invention.

FIG. 9 depicts one example of the structure of FIG. 8 after etching the layer of mandrel material (e.g., silanol) to achieve square-shaped mandrels (including the mandrel from FIG. 1), in accordance with one or more aspects of the present invention.

FIGS. 10a-10c depict simplified top-down views of examples of different ways to arrange closed-loop fins, made with a rectangular mandrel, and a gate to form a transistor: FIG. 10a showing a closed-loop fin, including a drain on one side, a source on an opposite side with a gate surrounding two channels; FIG. 10b showing a longer closed-loop fin, including a drain on one end, two sources opposite the drain and a gate, surrounding two channels; and, FIG. 10c showing a portion of a closed-loop fin, including a source, a drain and a long channel that is U-shaped and surrounded by a gate, in accordance with one or more aspects of the present invention.

FIGS. 11a-11d depict simplified top-down views of examples of various semiconductor devices that can be fabricated using closed-loop fins: FIG. 11a showing a CMOS inverter, including two portions of p-type and n-type, respectively, closed-loop fins with a gate surrounding and a contact electrically coupling ends of the closed-loop fin portions, and a remainder of the closed-loop fin portions electrically coupled to Vdd, Vss, and two Vouts as shown; FIG. 11b showing another inverter, including a p-type and an n-type closed-loop fin with Vdd and Vss on corresponding ends of the closed-loop fins, a gate spanning two opposite sides of each closed-loop fin and a contact spanning the bottom U-shaped portions and acting as Vout; FIG. 11c showing two p-type closed-loop fin-based transistors in parallel with a gate spanning two sides (channels) of each transistor, along with a corresponding circuit diagram; and, FIG. 11d showing two n-type closed-loop fin-based transistors in series, each having its own gate, along with a corresponding circuit diagram, in accordance with one or more aspects of the present invention.

FIG. 12 is a top-down view of one example of a six-transistor memory structure (SRAM) using closed-loop fin-based transistors, for example, a closed-loop fin, a part of which is used to form SRAM cells, in accordance with one or more aspects of the present invention.

FIG. 13 is a top-down view of one example of an eight-transistor memory structure (SRAM) using closed-loop fin-based transistors, for example, a closed-loop fin, part of which is used to form SRAM cells, in accordance with one or more aspects of the present invention.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

As used herein, unless otherwise specified, the term “about” used with a value, such as measurement, size, etc., means a possible variation of plus or minus five percent of the value. Also, unless otherwise specified, a given aspect of semiconductor fabrication described herein may be accomplished using conventional processes and techniques, where part of a method, and may include conventional materials appropriate for the circumstances, where a semiconductor structure is described.

Reference is made below to the drawings, which are not drawn to scale for ease of understanding, wherein the same reference numbers are used throughout different figures to designate the same or similar components.

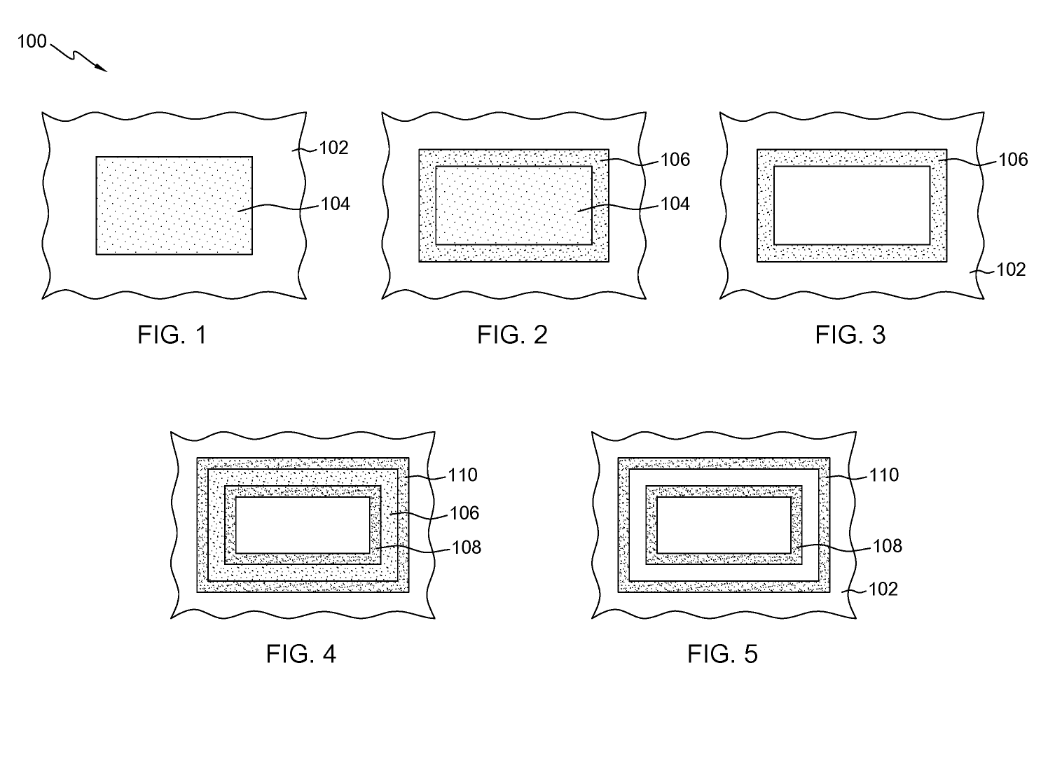

FIG. 1 is a top-down view of one example of a starting semiconductor structure 100, the structure including a base 102 (for example, a semiconductor substrate with hard mask layer thereover and a mandrel material on top) with a rectangular mandrel 104 (e.g., amorphous carbon) thereover, in accordance with one or more aspects of the present invention. The mandrel material can be a different type of material, so long as the etch is selective to hard mask below and spacer materials.

The starting structure may be conventionally fabricated, for example, using known processes and techniques. Further, unless noted otherwise, conventional processes and techniques may be used to achieve individual steps of the fabrication process of the present invention. However, although only a portion is shown for simplicity, it will be understood that, in practice, many such structures are typically included on the same bulk substrate.

In one example, the substrate of base 102 may include any silicon-containing substrate including, but not limited to, silicon (Si), single crystal silicon, polycrystalline Si, amorphous Si, silicon-on-nothing (SON), silicon-on-insulator (SOI) or silicon-on-replacement insulator (SRI) or silicon germanium substrates and the like. Substrate 102 may in addition or instead include various isolations, dopings and/or device features. The substrate may include other suitable elementary semiconductors, such as, for example, germanium (Ge) in crystal, a compound semiconductor, such as silicon carbide (SiC), gallium arsenide (GaAs), gallium phosphide (GaP), indium phosphide (InP), indium arsenide (InAs), and/or indium antimonide (InSb) or combinations thereof; an alloy semiconductor including GaAsP, AlInAs, GaInAs, GaInP, or GaInAsP or combinations thereof.

FIG. 2 depicts one example of the structure of FIG. 1 after forming a spacer 106 (e.g., oxide) around the mandrel 104, in accordance with one or more aspects of the present invention.

FIG. 3 depicts one example of the structure of FIG. 2 after removing the mandrel (104, FIG. 2), leaving closed-loop spacer 106, in accordance with one or more aspects of the present invention. In one example, the mandrel may be removed by plasma etching with selectivity to the spacer material.

FIG. 4 depicts one example of the structure of FIG. 3 after optionally forming inner and outer spacers (108 and 110, respectively) (e.g., nitride) around spacer 106 by using spacer 106 as a mandrel. The removal of the mandrel (i.e., spacer 106) may be performed, for example, using plasma etching with selectivity to the inner and outer spacer material, in accordance with one or more aspects of the present invention.

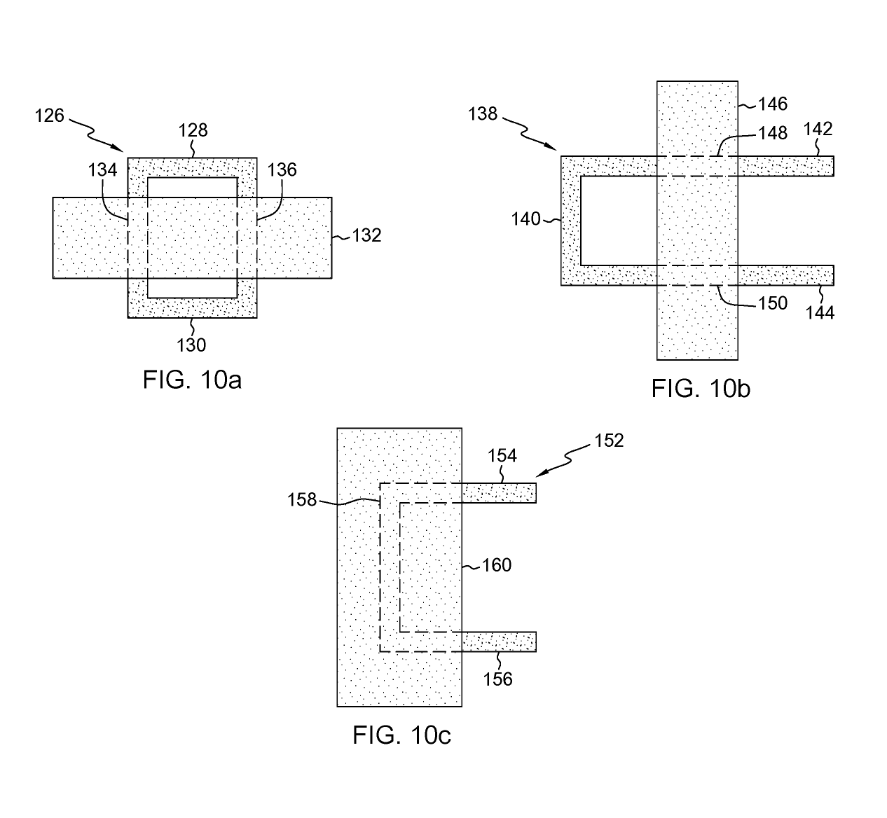

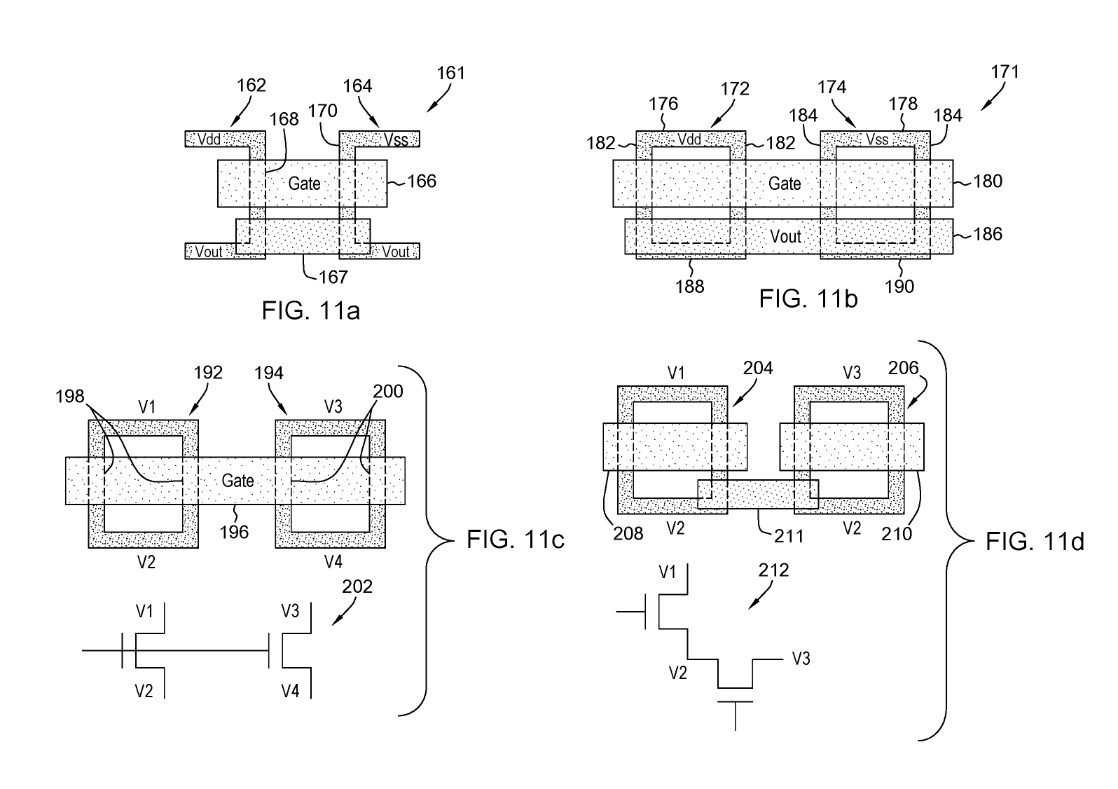

FIG. 5 depicts one example of the structure of FIG. 4 after removing the mandrel (106, FIG. 4) using a selective etch, in accordance with one or more aspects of the present invention. In one example, spacer 106 may be used as a mandrel. The removal of the mandrel (i.e., spacer 106) may be performed, for example, using plasma etching with selectivity to the inner and outer spacer material. In one example, spacers 108 and 110 may be used as an etching mask to form a closed-loop fin(s). Forming the closed-loop fin(s) may be accomplished by, for example, continuously performing plasma etching into the base 102. After removing the etch mask, a closed-loop fin(s) with hard-mask cap on top may be formed. As another example, with additional fin cut mask and etching steps, the close-loop fin(s) may be cut into U-shaped open-loop fins (see FIGS. 10 and 11).

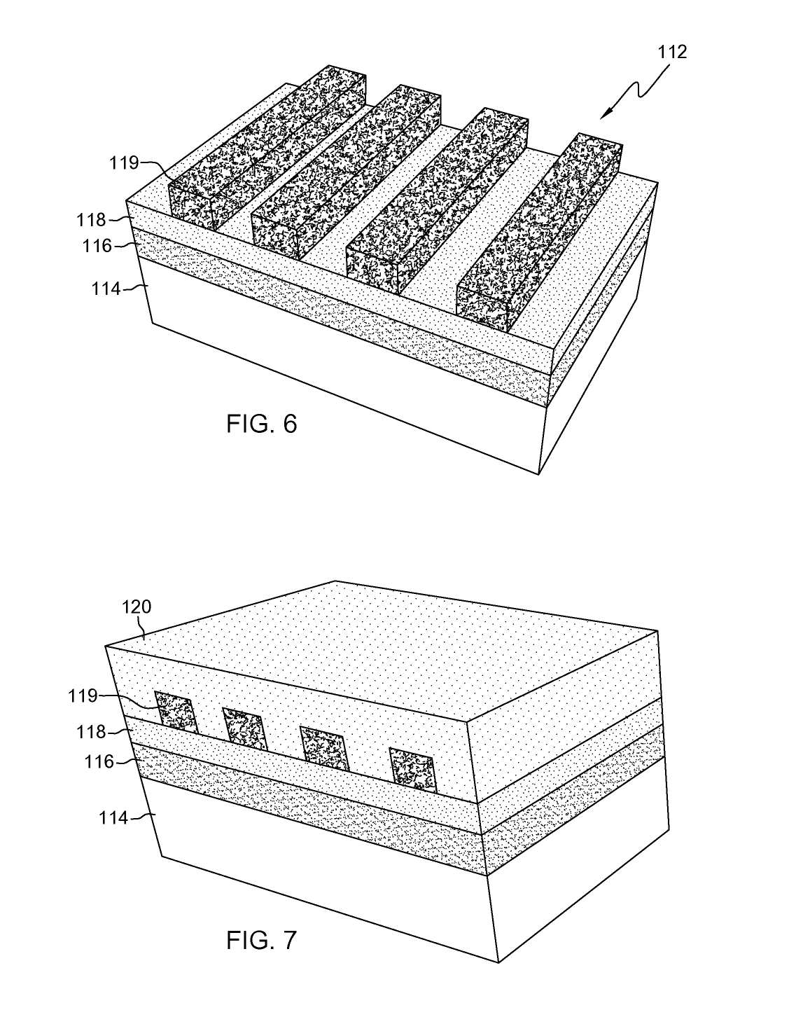

FIG. 6 depicts a three-dimensional perspective view of one example of a starting semiconductor structure 112 for fabrication of mandrel 104 in FIG. 1, the structure including a semiconductor substrate 114, hard mask layer 116 over the substrate, a layer 118 of dielectric material (e.g., silicon dioxide), and a layer 119 of mandrel material (e.g., silanol (Si—O—H)), previously patterned in the Y direction, in accordance with one or more aspects of the present invention. In one example, the Y direction patterning may be accomplished, for example, using a masking/lithographic process.

FIG. 7 depicts one example of the structure of FIG. 6 after formation of a blanket dielectric layer 120, for example, an organic dielectric material (ODL), followed by planarization (e.g., chemical-mechanical polishing process), in accordance with one or more aspects of the present invention.

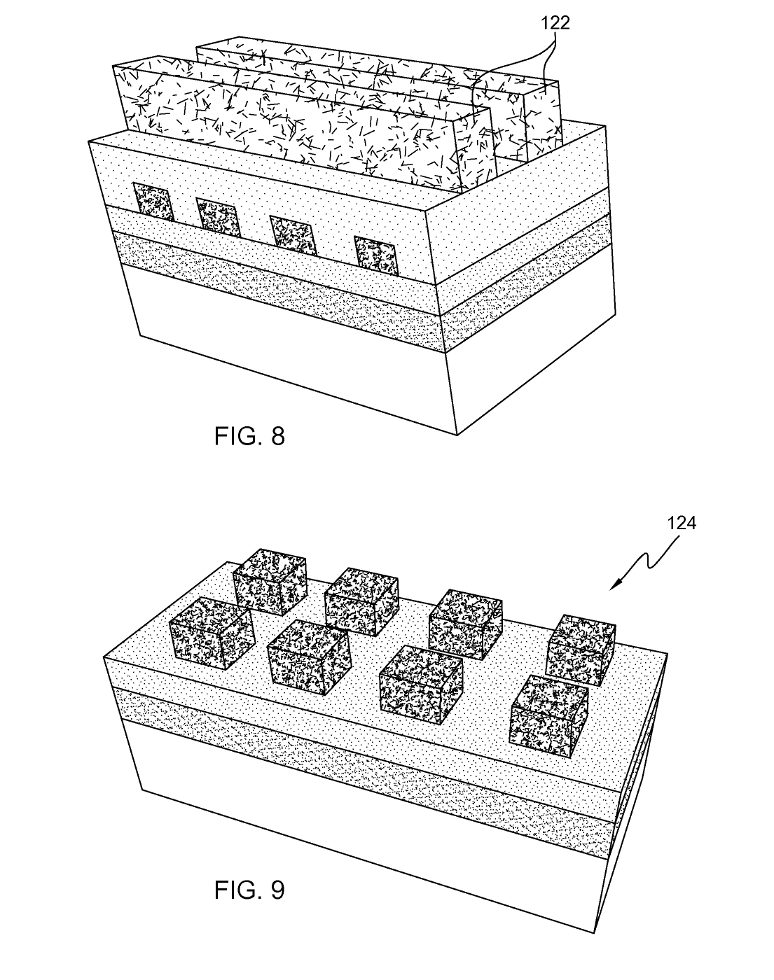

FIG. 8 depicts one example of the structure of FIG. 7 after formation and patterning of lithographic blocking layer 122 in the X direction, in accordance with one or more aspects of the present invention.

FIG. 9 depicts one example of the structure of FIG. 8 after etching the layer 119 of mandrel material into square-shaped mandrels 124 (including mandrel 104 from FIG. 1), in accordance with one or more aspects of the present invention. In one example, square shaped mandrel patterns can be formed, for example, by “Litho-Etch-Litho-Etch” (LELE) methods.

FIGS. 10a-10c depict simplified top-down views of examples of different ways to arrange closed-loop fins, for example, from the structure of FIG. 3, made with a rectangular mandrel, and a gate on top of the fins with a gate dielectric inbetween (not shown for simplicity) to form a transistor; FIG. 10a showing a closed-loop fin 126, including a drain 128 on one side, a source 130 on an opposite side with a gate 132 surrounding two channels 134 and 136; FIG. 10b showing a longer closed-loop fin 138 with a cut at one end, creating a U-shaped open loop, including a drain 140 on one end, two sources 142 and 144 opposite the drain and a gate 146, surrounding two channels 148 and 150; and, FIG. 10c showing a portion 152 of a cut closed-loop fin including a source 154, a drain 156 and a long channel 158 that is U-shaped and surrounded by a gate 160, in accordance with one or more aspects of the present invention.

FIGS. 11a-11d depict simplified top-down views of examples of various semiconductor devices that can be fabricated using closed-loop fins: FIG. 11a showing a CMOS inverter 161, including two portions 162 and 164 of p-type and n-type, respectively, U-shaped open-loop fins with a gate 166 on top and a contact 167 electrically coupling ends 168 and 170 of the U-shaped open-loop fin portions (note, there are contacts on Vdd, Vss and Vout, not shown for simplicity), and a remainder of the open-loop fin portions electrically coupled to Vdd, Vss, and two Vouts as shown; FIG. 11b showing another inverter 171, including a p-type 172 and an n-type 174 closed-loop fins with Vdd and Vss on corresponding ends 176 and 178 of the closed-loop fins, a gate 180 spanning two opposite sides (182, 184) of each closed-loop fin and a contact 186 spanning bottom portions 188 and 190 acting as Vout; FIG. 11c showing two p-type closed-loop fin-based transistors 192 and 194 in parallel with a gate 196 spanning two sides 198, 200 (channels) of each transistor, along with a corresponding circuit diagram 202; and, FIG. 11d showing two n-type closed-loop fin-based transistors 204 and 206 in series, each having its own gate (208 and 210, respectively), the V2 of each transistor electrically connected by a contact 211 spanning both V2, along with a corresponding circuit diagram 212, in accordance with one or more aspects of the present invention.

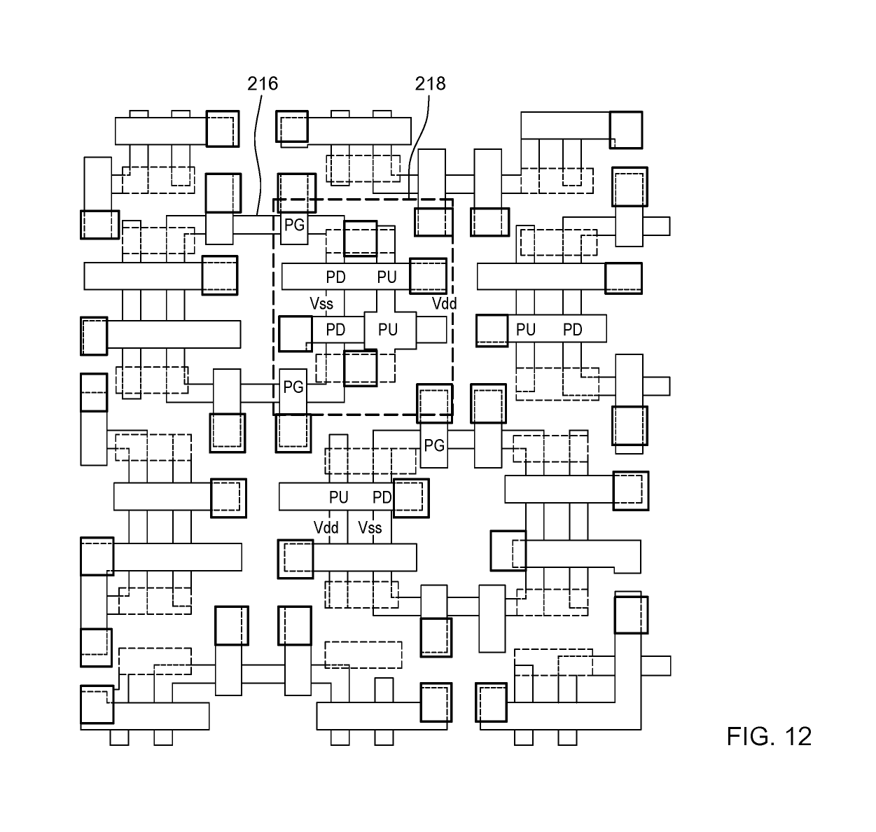

FIG. 12 is a top-down view of one example of a six-transistor memory structure (SRAM) 214 using closed-loop fin-based transistors, for example, closed-loop fin 216, a part of which is used to form SRAM cells (e.g., SRAM cell 218), in accordance with one or more aspects of the present invention. In one example, the pull up (PU) transistor, pull-down (PD) transistor, and pass gate (PG) transistor are p-type, n-type, and n-type, respectively.

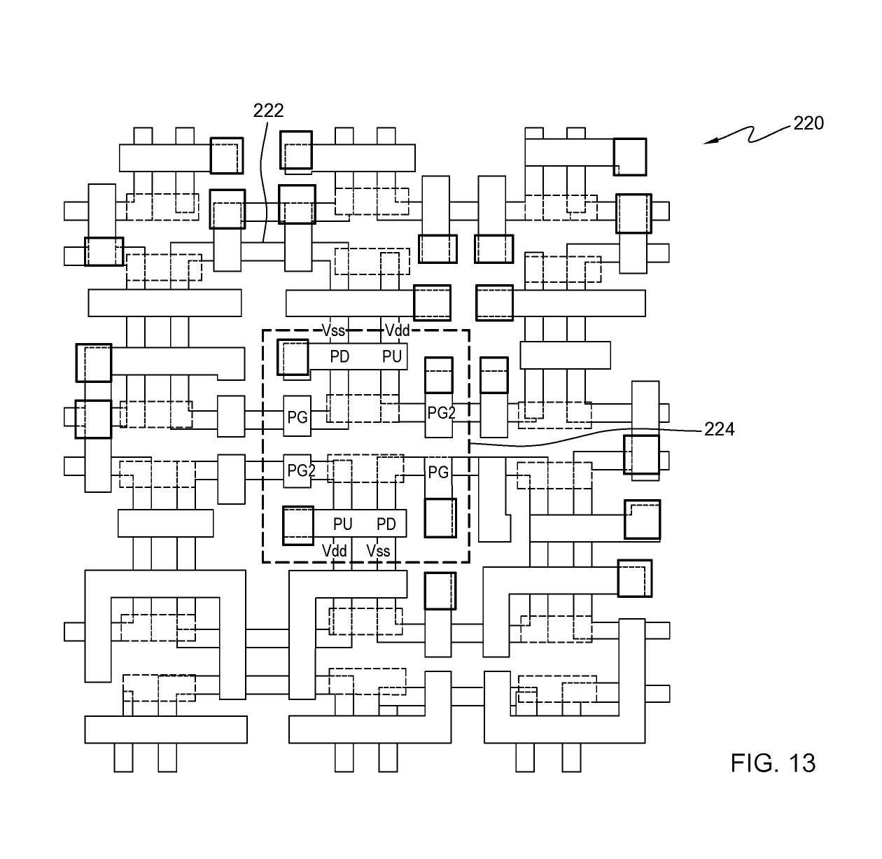

FIG. 13 is a top-down view of one example of an eight-transistor SRAM structure 220 using closed-loop fin-based transistors, for example, closed-loop fin 222, part of which is used to form SRAM cells (e.g., SRAM cell 224), in accordance with one or more aspects of the present invention.

In a first aspect, disclosed above is a method. The method includes forming rectangular mandrel(s), forming closed-loop spacer(s) around the rectangular mandrel(s), and removing the rectangular mandrel(s), leaving the closed-loop spacer(s).

In one example, the method may further include, for example, prior to forming the closed-loop spacer(s), providing a starting structure, the starting structure including a semiconductor substrate, a dielectric layer over the semiconductor substrate, a first hard mask layer over the dielectric layer and a second hard mask layer over the first hard mask layer, the first hard mask layer and the second hard mask layer having different etch susceptibilities, the closed-loop spacer(s) being formed over the starting structure.

In one example, the method may further include, for example, forming closed-loop fin(s) using the closed-loop spacer(s).

In one example, the method of the first aspect may further include, for example, for at least one of the closed-loop spacer(s), forming inner and outer closed-loop spacers adjacent the at least one of the closed-loop spacer(s), and removing the at least one of the closed-loop spacer(s).

In one example, forming the closed-loop fin(s) may include, for example, using masking and lithography. In one example, the masking and lithography may include, for example, a first process of masking and lithography in one of a X direction and a Y direction, and a second process of masking and lithography in another of the X direction and the Y direction.

In one example, the method may further include, for example, cutting at least one of the closed-loop fin(s).

In a second aspect, disclosed above is a transistor. The transistor includes U-shaped portion(s) of a closed-loop fin, and a gate across channel region(s) of the U-shaped portion(s) of a closed-loop fin.

In one example, the U-shaped portion(s) may include, for example, two joined U-shaped portions, the two joined U-shaped portions forming a closed-loop fin. In one example, the gate may be, for example, situated across two opposite sides of the closed-loop fin.

In a third aspect, disclosed above is a semiconductor structure. The semiconductor structure includes portion(s) of closed-loop fin(s), and transistors formed from the portion(s) of closed-loop fin(s).

In one example, the portion(s) may include, for example, one U-shaped portion of a closed-loop fin, and the transistors may include, for example, six transistors forming a SRAM memory cell.

In one example, the closed-loop fin(s) may include, for example, four closed-loop fins, the portion(s) including a corner portion, and the transistors each include eight transistors forming a SRAM memory cell.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a starting semiconductor structure, the starting semiconductor structure comprising a semiconductor substrate and a first hard mask layer thereover;
forming one or more rectangular mandrels over the hard mask layer;
forming one or more closed-loop spacers around the one or more rectangular mandrels;
removing the one or more rectangular mandrels, leaving the one or more closed-loop spacers; and
using the one or more closed-loop spacers to form one or more closed-loop fins for fabricating one or more FinFET-based semiconductor devices.

2. The method of claim 1, wherein the starting semiconductor structure further comprises:
a dielectric layer over the semiconductor substrate and under the first hard mask layer; and
a second hard mask layer over the first hard mask layer, the first hard mask layer and the second hard mask layer having different etch susceptibilities, wherein the one or more closed-loop spacers are formed over the starting semiconductor structure.

3. (canceled)

4. The method of claim 2, wherein a material of the one or more rectangular mandrels is etch-selective to the second hard mask layer and the one or more closed-loop spacers.

5. The method of claim 1, further comprising:
for at least one of the one or more closed-loop spacers, forming inner and outer closed-loop spacers adjacent the at least one of the one or more closed-loop spacers; and
removing the at least one of the one or more closed-loop spacers.

6. The method of claim 5, wherein forming the one or more closed-loop fins comprises using masking and lithography.

7. The method of claim 6, wherein the masking and lithography comprises:
a first process of masking and lithography in one of a X direction and a Y direction; and
a second process of masking and lithography in another of the X direction and the Y direction.

8. The method of claim 1, further comprising cutting at least one of the one or more closed-loop fins.

9. The method of claim 1, wherein removing the one or more rectangular mandrels comprises using plasma etching selective to a material of the one or more closed-loop spacers.

10. A transistor, comprising:
at least one U-shaped portion of a closed-loop fin;
a gate across at least one channel region of the at least one U-shaped portion of a closed-loop fin.

11. The transistor of claim 10, wherein the at least one U-shaped portion comprises two joined U-shaped portions, the two joined U-shaped portions forming a closed-loop fin.

12. The transistor of claim 11, wherein the gate is situated across two opposite sides of the closed-loop fin.

13. A semiconductor structure, comprising:
at least one portion of one or more closed-loop fins; and
a plurality of transistors formed from the at least one portion of one or more closed-loop fins.

14. The semiconductor structure of claim 13, wherein the at least one portion comprises one U-shaped portion of a closed-loop fin, and wherein the plurality of transistors comprises six transistors forming a SRAM memory cell.

15. The semiconductor structure of claim 14, wherein the one or more closed-loop fins comprises four closed-loop fins of each of the four closed-loop fins, wherein the at least one portion comprises a corner portion, and wherein the plurality of transistors comprises eight transistors forming a SRAM memory cell.
